(19) United States
(12) Patent Application Publication
(10) Pub. No.: US 2025/0246590 A1
(43) Pub. Date: Jul. 31, 2025

(54) INTEGRATED DEVICES HAVING MULTIPLE DIE ORIENTATIONS

(71) Applicant: QUALCOMM Incorporated, San Diego, CA (US)

(72) Inventors: Yujen CHEN, Taichung (TW); Aniket PATIL, San Diego, CA (US); Yangyang SUN, San Diego, CA (US)

(21) Appl. No.: 18/422,127

(22) Filed: Jan. 25, 2024

(51) Int. Cl. H01L 25/00; H01L 21/56; H01L 23/00; H01L 25/18; H10B 80/00

(52) U.S. Cl. CPC H01L 25/50; H01L 24/19; H01L 24/20; H01L 25/18; H10B 80/00; H01L 21/561; H01L 21/568; H01L 2224/19; H01L 2224/211

(57) ABSTRACT

A device includes a first die physically and electrically connected to a first set of redistribution layers, where the first set of redistribution layers include a first set of metal layers oriented along a first plane. The integrated device also includes a substrate and a second die disposed between the first set of redistribution layers and the substrate. The second die is physically and electrically connected to a second set of redistribution layers, where the second set of redistribution layers include a second set of metal layers oriented along a second plane. The second plane is non-parallel with respect to the first plane, and the second set of metal layers define conductive paths between various combinations of the substrate, the first die, and the second die.

### FIELD

Various features relate to integrated devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art integrated devices for many applications (such as mobile devices, internet-of-things devices, automotive, etc.) demand a small form factor, low cost, a tight power budget, and high electrical performance. Integrated circuit (IC) package design has evolved to meet these divergent goals. However, semiconductor fabrication technology improvements continue to enable fabrication of smaller dies with more input/output connections, which leads to challenges with providing IC packages that are able to provide enough interconnects while meeting other design goals.

### SUMMARY

Various features relate to integrated devices.

One example provides a device that includes a first die physically and electrically connected to a first set of redistribution layers. The first set of redistribution layers includes a first set of metal layers oriented along a first plane. The integrated device also includes a substrate and a second die disposed between the first set of redistribution layers and the substrate. The second die is physically and electrically connected to a second set of redistribution layers. The second set of redistribution layers includes a second set of metal layers oriented along a second plane. The second plane is non-parallel with respect to the first plane, and the second set of metal layers define conductive paths between various combinations of the substrate, the first die, and the second die.

Another example provides a method for fabricating a device. The method includes forming a structure that includes a substrate, a first set of redistribution layers physically and electrically connected to a first die, and a second set of redistribution layers interconnected with the first set of redistribution layers. The first set of redistribution layers includes a first set of metal layers oriented along a first plane, and the second set of redistribution layers includes a second set of metal layers oriented along a second plane that is non-parallel with respect to the first plane. The substrate includes a third set of metal layers oriented along a third plane that is parallel to the second plane. The method also include electrically connecting a second die to the second set of redistribution layers to define conductive paths between the first die and the second die though the second set of redistribution layers and the first set of redistribution layers.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a schematic cross-sectional view of an example of a device that includes dies oriented in multiple different directions.

FIG. 2 illustrates a schematic cross-sectional view of an example of a device that includes dies oriented in multiple different directions.

FIGS. 3A, 3B, 3C, and 3D together illustrate an exemplary sequence for fabricating an example of a device that includes dies oriented in multiple different directions.

FIG. 4 illustrates an exemplary flow diagram of a method for fabricating an example of a device that includes dies oriented in multiple different directions.

FIG. 5 illustrates various electronic devices that may include an integrated device including a device that includes dies oriented in multiple different directions, as described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

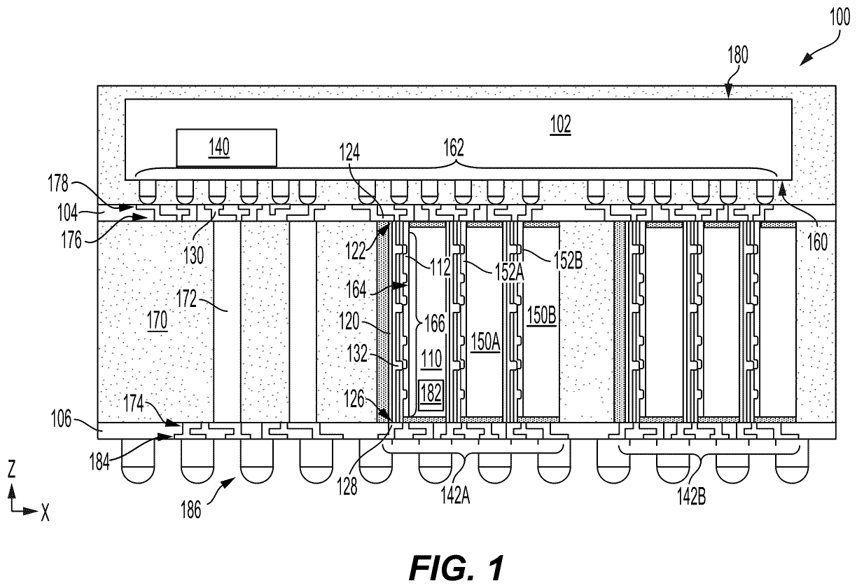

In some drawings, multiple instances of a particular type of feature are used. Although these features are physically and/or logically distinct, the same reference number is used for each, and the different instances are distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple die stacks are illustrated and associated with reference numbers 142A and 142B. When referring to a particular one of these die stacks, such as a die stack 142A, the distinguishing letter “A” is used. However, when referring to any arbitrary one of these die stacks or to these die stacks as a group, the reference number 142 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. A chip-first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Many advances in computing technology have been facilitated by providing semiconductor chips that include more complex circuitry. One metric that is often used as an indication of the complexity of semiconductor devices is transistor count. For example, the observation commonly referred to as “Moore's Law” indicates that, as technology improves, the number of transistors in integrated circuits tends to double about every two years. Historically, this increase in transistor count has been supported by improvements in technology that enabled fabrication of smaller circuit elements (e.g., transistors, interconnects, etc.) and fabrication of larger dies. Additional improvements have occurred that enable more intimate interconnection among different functional blocks of an integrated circuit, such as integration of many functional blocks into a single die as a “system on a chip.” While these changes have improved performance of computer systems and related technologies, they have also introduced additional challenges. For example, die yield tends to decrease as the size of the die increases, so larger dies tend to drive up manufacturing costs. As another example, smaller circuit features (which is an aspect of the technology node used to fabricate an integrated circuit) tend to be more useful in some types of circuitry (e.g., in certain functional blocks) than in other types. To illustrate, many key functional metrics associated with processor cores (such as measures of operations per second or power utilization) tend to improve when designers are able to use smaller, more closely packed transistors; however, metrics associated with other related circuits, such as physical interface circuits, tend to benefit less from the use of smaller, more closely packed transistors.

Forming a device using chiplets arranged and interconnected as a 3D stacked IC can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one die of a chiplet-based integrated device can include components (e.g., interconnects, transistors, etc.) that have a first minimum size, and another die of the chiplet-based integrated device can include components (e.g., interconnects, transistors, etc.) that have a second minimum size, where the second minimum size is greater than the first minimum size. When manufacturing a monolithic die, all of the circuitry of the die is fabricated using the same fabrication technologies and equipment and is subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. Chiplets fabricated using less expensive and/or higher yield fabrication technologies can be integrated with chiplets fabricated using more expensive and/or lower yield fabrication technologies to form an IC, resulting in overall savings. Still further, in some cases, as technology improves, the design of a chiplet can be changed. Chiplet stacking allows such new chiplet designs to be integrated with older chiplet designs to form stacked IC devices, which improves manufacturing flexibility and reduces design costs.

While chiplet-based architectures have many benefits, they are not without challenges. For example, in monolithic dies, interconnections between functional blocks are fabricated within the semiconductor die. However, when functional blocks are split between multiple chiplets, interconnections therebetween must be routed in some other manner at the package level. Routing of such interconnections at the package level is challenging because package-level interconnects tend to be larger and longer than chip-level interconnects. For example, semiconductor fabrication techniques form circuits on a singles side of a wafer; however, it is often the case that two chiplets need to be interconnected with one another as well as to off-package components via a package substrate. As a result, interconnects between the dies, interconnects between one of the dies and the package substrate, or both, are generally routed through interconnects that extend the full thickness of one of the chiplets. To illustrate, a bottom chiplets of a 3D chiplet stack can include through silicon vias (TSVs) that form part of the interconnects between one of the chiplets and the package substrate. Forming TSVs is expensive and reduces die yield. Additionally, TSVs take up space within the bottom chiplet that could be used for other circuitry, which tends to increase the size of the chiplet. The size of the bottom chiplet may also be increased to reduce signal interference between signals routed in the TSVs and signal routed among circuit elements of the bottom chiplet.

Disclosed embodiments provide chiplet-to-chiplet interconnects in a 3D stacked IC device in a manner that can avoid the use of TSVs. The disclosed embodiments can also enable die-to-die interconnection in situations where the dies are not specifically chiplets, such as interconnection between a logic die and one or more memory dies.

In a particular aspect, a stacked IC device includes dies oriented in different directions and interconnected through redistribution layers (RDLs). For example, in a 3D space characterized by orthogonal X-, Y-, and Z-axes, a first die can be coupled to first RDLs and oriented parallel to an XY plane, and a second die can be coupled to second RDLs and oriented parallel to an YZ plane. In this example, the second RDLs are electrically connected to the first RDLs to provide conductive paths between the first and second dies. Additionally, the second RDLs can be electrically connected to a package substrate to provide conductive paths between the package substrate and either or both of the first and second dies.

As one example, the disclosed embodiments can be used in a chiplet architecture in which physical-layer functional blocks, such as analog circuitry, universal serial bus (USB) circuitry, ethernet circuitry, peripheral component interconnect circuitry, various memory interface circuitry, etc. can be disposed in one or more chiplets that are interconnected, through RDLs in different orientations, to other dies, such as memory dies or logic dies. In some cases, 10-20% of the footprint of a processor device or a system-on-chip (SOC) device can be dedicated to such physical-layer functional blocks. Thus, moving some or all of these physical-layer functional blocks to other chiplets can result in much smaller processor or SOC dies, providing corresponding yield increases and cost savings. Additionally, in some cases, chiplets that include the physical-layer functional blocks can be fabricated using less expensive processes, resulting in further savings. To illustrate, the size of some analog circuit elements in physical-layer functional blocks is constrained due to functional requirements, and fabricating such circuit elements using very advanced fabrication techniques used for complex processor cores is needlessly expensive. Additionally, physical-layer functional blocks may be the same for several different processor or SOC products. Thus, separating the physical-layer functional blocks to chiplets arranged as disclosed enables reuse of the same physical-layer functional blocks as chiplets in multiple different product lines, providing further savings and process simplification.

The disclosed techniques can be used for 3D stacking of chiplets other than or in addition to chiplets that include physical-layer functional blocks. For example, memory dies and processor dies can be stacked and interconnected as described herein. As another example, dies that include multiple processors or processor cores (e.g., CPUs and GPUs), dies that include passive components (e.g., inductors or capacitors to facilitate impedance matching or to improve power distribution network performance), etc. can be stacked and interconnected using the disclosed techniques.

### Exemplary Integrated Devices Having Multiple Die Orientations

FIG. 1 illustrates a schematic cross-sectional view of an example of a device 100 that includes multiple dies in a stacked arrangement. In particular, the device 100 includes a substrate 106, a die 102, and a die 110 disposed between the substrate 106 and the die 102. In the example illustrated in FIG. 1, the die 110 is part of a die stack 142A that also includes one or more additional dies 150 (such as a die 150A and a die 150B). The device 100 may also include one or more additional die stacks, such as a die stack 142B.

The substrate 106 includes two or more metal layers separated from one another by dielectric layer(s). The metal layers are patterned to define contacts (e.g., contacts 174 of a first metal layer and contacts 184 of a second metal layer), traces, and possibly other conductive features. The metal layers of the substrate 106 are interconnected to one another by conductive vias to define conductive paths between the contacts 174 and the contacts 184. The contacts 184 can be electrically connected to other devices or substrates using interconnects 186 (e.g., a ball grid array or another set of interconnects). In some embodiments, a first contact of the contacts 174 can be electrically connected, via traces defined in one or more metal layers of the substrate 106, to a second contact of the contacts 174. The substrate 106 can include a cored or coreless laminate substrate or a set of redistribution layers. In some embodiments, the substrate 106 can include one or more electronic components on a surface of the substrate 106, one or more electronic components embedded within the substrate 106, or both. For example, one or more capacitive devices can be in or on the substrate 106 and electrically connected, through the metal layers of the substrate 106 and other conductors, to the die 102 and/or to one or more dies of the die stack(s) 142.

The die 102 includes integrated circuitry 140, and a plurality of contacts 162 electrically connected to the integrated circuitry 140. The integrated circuitry 140 includes active circuit elements (e.g., transistors) and may also include various passive circuit elements (e.g., resistors, inductors, capacitors, etc.). The contacts 162 are disposed on a face 160 of the die 102. In the context of this disclosure, a “face” of a die refers to a surface of the die adjacent to an active region of the die. For example, the active region can include various layers and structures that define the integrated circuitry 140. In this example, the face of the die corresponds to the side of the die that bounds the active region. In contrast, a “back” of a die (e.g., back 180 of die 102) refers to an opposite side of the die which bounds an inactive region of the die. For example, the inactive region typically includes undoped monocrystalline semiconductive material, other inactive layers (e.g., passivation layers), or both.

The contacts 162 are physically and electrically connected to redistribution layers (RDLs) 104. The RDLs 104 include two or more metal layers separated from one another by dielectric layer(s). The metal layers are patterned to define contacts (e.g., contacts 176 of a first metal layer and contacts 178 of a second metal layer), traces, and possibly other conductive features. The metal layers of the RDLs 104 are also interconnected to one another by conductive vias 130 to define conductive paths between the contacts 176 and the contacts 178.

The die 110 includes integrated circuitry 182, such as active circuit elements, passive circuit elements, or a combination thereof. The die 110 also includes a plurality of contacts 166 disposed on a face 164 of the die 110 and electrically connected to the integrated circuitry 182.

The contacts 166 are physically and electrically connected to RDLs 112. The RDLs 112 include two or more metal layers separated from one another by dielectric layer(s). The metal layers are patterned to define contacts, traces (e.g., a trace 120), and possibly other conductive features. The metal layer of the RDLs 112 are also interconnected to one another by conductive vias 132 to define conductive paths between the contacts 166 and various traces of the metal layers.

The metal layers of the RDLs 104 are oriented along a first plane, and the metal layers of the RDLs 112 are oriented along a second plane that is non-parallel to the first plane. For example, FIG. 1 shows a Z-axis and an X-axis of a three-dimensional coordinate system, and a Y-axis of the coordinate system is oriented into or out of the page including FIG. 1. In this example, the metal layers of the RDLs 104 are oriented parallel to an XY-plane, and the metal layers of the RDLs 112 are oriented parallel to a ZY-plane. Similarly, the face 160 of the die 102 is oriented toward the substrate 106 (e.g., a normal of a surface corresponding to the face 160 is oriented along a negative Z direction), and the face 164 of the die 110 is oriented toward a side of the device 100 (e.g., a normal of a surface corresponding to the face 164 is oriented along a negative X direction).

In a particular aspect, at least one of the contacts 166 of the die 110 is electrically connected to at least one of the contacts 162 of the die 102 via the RDLs 112 and the RDLs 104. For example, a trace 120 of the RDLs 112 can be electrically connected, at an end 122, to a contact 124 of the contacts 176 of the RDLs 104. In this example, the trace 120 can be electrically connected, by one of the vias 132 and optionally by contacts or traces of another metal layer of the RDLs 112, to one of the contacts 166 of the die 110. Further, in this example, the contact 124 is electrically connected, by one or more of the vias 130 and optionally features of one or more additional metal layers of the RDLs 104, to one of the contacts 178, which is electrically connected to the die 102. Thus, a conductive path between the die 102 and the die 110 includes conductors of the RDLs 104 and conductors of the RDLs 112. Further, in this example, the conductive path between the die 102 and the die 110 does not include any conductor of the substrate 106 and does not include any through-silicon via.

In some embodiments, at least one of the contacts 166 of the die 110 is electrically connected to one of the contacts 174 of the substrate 106 via the RDLs 112. For example, in some such embodiments, the trace 120 of the RDLs 112 is electrically connected, at an end 126, to a contact 128 of the contacts 174. In this example, the trace 120 can be electrically connected, by one of the vias 132 and optionally by contacts or traces of another metal layer of the RDLs 112, to one of the contacts 166 of the die 110. The contact 128 may be electrically connected, by one or more of the vias and optionally one or more metal layers of the substrate 106, to one of the contacts 184. Thus, in such embodiments, a conductive path between the die 110 and an off-package contact (e.g., one of the contacts 184) can include conductors of the RDLs 112 and conductors of the substrate 106.

In some embodiments, the device 100 can include additional conductors electrically connecting the RDLs 104 and the substrate 106. To illustrate, in FIG. 1, the device 100 includes a mold compound 170 between the substrate 106 and the RDLs 104. The mold compound 170 at least partially encapsulates the die 110 (and other dies of the die stack 142A), and one or more through mold vias (TMVs) 172 extend through the mold compound 170. Each of the TMV(s) 172 is electrically connected to one of the contacts 176 and to one of the contacts 174. In such embodiments, one or more of the contacts 162 are electrically connected to an off-package contact (e.g., one of the contacts 184) by one of the TMVs 172.

Additionally, or alternatively, in some embodiments, one or more of the contacts 162 is electrically connected to an off-package contact (e.g., one of the contacts 184) by one or more metal traces of the RDLs 112. To illustrate, in such an embodiment, the trace 120 of the RDLs 112 may be electrically connected to the contact 128 at the end 126 and to the contact 124 at the end 122. In this example, the trace 120 electrically connects the contacts 124, 128 to form a portion of a conductive path between the die 102 and the off-package contacts (e.g., contacts 184).

When the die 110 is part of a die stack 142A including one or more additional dies 150, as in the example illustrated in FIG. 1, each of the additional dies 150 may be physically and electrically connected to a corresponding set of RDLs. For example, the die 150A of FIG. 1 is physically and electrically connected to RDLs 152A, and the die 150B is physically and electrically connected to RDLs 152B. Each of the RDLs 152 includes two or more metal layers electrically connected to contacts of a die 150. The metal layers of the RDLs 152 are oriented substantially parallel to the metal layers of the RDLs 112 (and non-parallel to the metal layers of the RDLs 104). Further, the metal layers of the RDLs 152 are interconnected by vias that are oriented along a direction (e.g., the X direction) parallel to a direction of the vias 132 of the RDLs 112 (and non-parallel to a direction of the vias 130). The metal layers define traces that define portions of conductive paths between combinations of the die 150, the die 102, and the substrate 106. Further, in some embodiments, conductive paths between the die 110 and one of the dies 150 can be defined by electrical connections between one or more traces of the RDLs 112, one or more traces of the substrate 106, and one or more traces of the RDLs 152, or can be defined by electrical connections between one or more traces of the RDLs 112, one or more traces of the RDLs 104, and one or more traces of the RDLs 152.

Interconnecting the die 102 with dies of the die stack(s) 142 in the manner illustrated in FIG. 1 enables three-dimensional stacking of the dies of an integrated device (e.g. the device 100) in a low-cost manner. For example, in some embodiments, a multi-die die stack (e.g., a die stack 142) can be interconnected with the die 102 without the use of TSVs. TSVs increase semiconductor fabrication costs, decrease yield, and increase dic size. Accordingly, embodiments disclosed herein can decrease semiconductor fabrication costs, increase yield, and/or decrease die size relative to devices that use TSVs.

In some embodiments, the die stack 142 includes one or more chiplets configured to cooperate with the die 102. For example, the circuitry 140 of the die 102 can define one or more processor cores, and one or more dies of the die stack 142 can include physical-layer interface circuitry (e.g., the circuitry 182) associated with the circuitry 140. As another example, the circuitry 140 of the die 102 can define one or more processor cores, and the one or more dies of the die stack 142 can include circuitry (e.g., the circuitry 182) defining a plurality of memory elements. Other arrangements of cooperative dies can also be interconnected in the manner illustrated in FIG. 1. In some embodiments, one or more of the dies of the die stack 142 include passive circuit elements that support operation of the die 102. For example, the die 150A can include one or more embedded capacitive devices that are electrically connected, via the RDLs 152A, to a power distribution network of the die 102.

Although the device 100 of FIG. 1 is illustrated as including two die stacks 142, with each die stack 142 including three dies, in other embodiments, the device 100 can include more than two die stacks 142 or fewer than two die stacks 142, and each die stack can include more than three dies or fewer than three dies. Further, in examples of the device 100 that include two or more die stacks 142, the die stacks 142 can include different numbers of dies (e.g., a first die stack can include two dies and a second die stack can include five dies). In some cases, two dies of a die stack 142 can include substantially similar circuitry. For example, a die stack 142 can include multiple substantially similar memory dies. In some cases, two dies of a die stack 142 can include different circuitry. For example, a die stack can include a first die including first physical-layer circuitry (e.g., Ethernet physical-layer circuitry) and a second die including memory circuitry or second physical-layer circuitry (e.g., USB physical-layer circuitry).

In FIG. 1, the two die stacks 142 are illustrated as having the same orientation. For example, metal layers of RDLs of the die stack 142A (e.g., the RDLs 112, 152A and 152B) are oriented parallel to the ZY plane, and metal layers of RDLs of the die stack 142B are also oriented parallel to the ZY plane. However, in other examples, the device 100 can include die stacks 142 with different orientations. To illustrate, the metal layers of RDLs of the die stack 142A can be oriented parallel to the ZY plane, and the metal layers of RDLs of the die stack 142B can be oriented parallel to the XY plane or in some other orientation (e.g., angled with respect to the ZY plane). As another example, in FIG. 1, normal vectors of faces of the dies of the dies stack 142A are oriented along a negative X direction, and normal vectors of faces of the dies of the dies stack 142B are also oriented along the negative X direction. However, in other examples, the normal vectors of faces of the dies of the dies stack 142A are angularly offset from or antiparallel to the normal vectors of faces of the dies of the dies stack 142B.

In FIG. 1, the device 100 is illustrated as including a single top die (e.g., the die 102); however, in some embodiments, the device 100 can include two or more top dies. For example, two or more logic dies (e.g., a CPU die and a GPU die) can be electrically connected to the RDLs 104 and electrically connected, through the RDLs 104 and RDLs of one or more die stacks 142 to dies of the die stack(s) 142. In such embodiments, the two or more logic dies may also be electrically connected to one another via the RDLs 104.

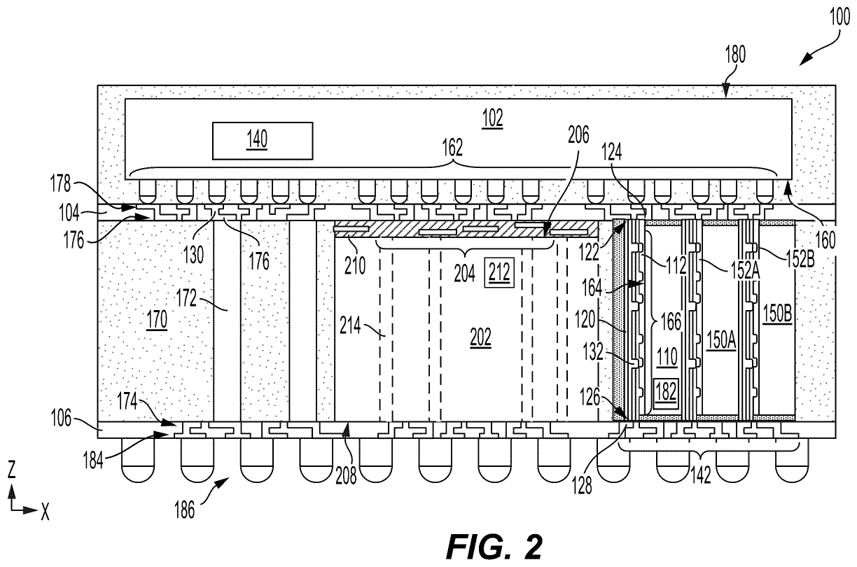

FIG. 2 illustrates a schematic cross-sectional view of another example of the device 100. The device 100 of FIG. 2 can include any or all of the features, aspects, and alternative configurations described with reference to the device 100 of FIG. 1. For example, in FIG. 2, the device 100 includes the substrate 106, the die 102, and one or more die stacks 142. The die 102 and the die stack(s) 142 are electrically connected to one another by conductive paths through RDLs 104 and RDLs 112, as described with reference to FIG. 1. Further, in some embodiments, the die 102 is electrically connected to the substrate 106 by one or more conductive paths through the RDLs 104 and the RDLs 112, by one or more conductive paths through the RDLs 104 and one or more TMVs 172, or both. Additionally, in some embodiments, one or more dies 110, 150 of the die stack(s) 142 are electrically connected to the substrate 106 by one or more conductive paths through the RDLs 112.

Additionally, the device 100 of FIG. 2 includes a die 202 disposed between the RDLs 104 and the substrate 106. The die 202 includes integrated circuitry 212 that is configured to cooperate with the circuitry 140 of the die 102, with circuitry of dies of a die stack 142 (e.g., with the circuitry 182 of the die 110 and/or circuitry of a die 150), or both. The circuitry 212 can include active circuit elements, passive circuit elements, or a combination thereof. For example, the circuitry 212 can define one or more processor cores, physical-layer interface circuitry associated with the circuitry 140, a plurality of memory elements, passive circuit elements that support operation of the die 102 (e.g., capacitive devices electrically connected to a power distribution network of the die 102), or combinations thereof.

The die 202 is oriented such that a normal vector of a face 206 of the die 202 is oriented parallel to or antiparallel to a normal vector of the face 160 of the die 102 and non-parallel to a normal vector of a face of the die 110 of the die stack 142. In FIG. 2, the die 202 is shown in a “face-up” orientation in which a back 208 of the die 202 is coupled to the substrate 106 and the face 206 of the die 202 is away from the substrate 106. In other embodiments, the die 202 can be in a “face-down” orientation in which the face 206 of the die 202 is toward the substrate 106 and the back 208 of the die 202 is away from the substrate 106.

In the example illustrated in FIG. 2, RDLs 210 are disposed on the face 206 of the die 202 and electrically connected to contacts 204 on the face 206 of the die 202. The RDLs 210 include two or more metal layers separated from one another by dielectric layer(s). The metal layers are patterned to define contacts, traces, and possibly other conductive features. The metal layers of the RDLs 210 are also interconnected to one another by conductive vias to define conductive paths therebetween. The metal layers of the RDL(s) 210 are oriented parallel to the metal layers of the RDLs 104, and non-parallel with respect to metal layers of RDLs 112, 152 of the die stack(s) 142.

In the example illustrated in FIG. 2, the RDLs 210 form portions of conductive paths between the die 202 and other components of the device 100, such as the die 102, one or more dies of the die stack(s) 142, etc. In some embodiments, the RDLs 210 form portions of conductive paths between the die 202 and off-package components through the substrate 106. For example, the circuitry 212 of the die 202 can be electrically connected to the circuitry 140 of the die 102 via a conductive path that includes conductors of the RDLs 210 and conductors of the RDLs 104. As another example, the circuitry 212 of the die 202 can be electrically connected to the circuitry 182 of the die 110 via a conductive path that includes conductors of the RDLs 210 and conductors of the RDLs 112. As another example, the circuitry 212 of the die 202 can be electrically connected to off-package components via a conductive path that includes conductors of the RDLs 210, conductors of the RDLs 104, conductors of the RDLs 112, and conductors of the substrate 106. As still another example, the circuitry 212 of the die 202 can be electrically connected to off-package components via a conductive path that includes conductors of the RDLs 210, conductors of the RDLs 104, one or more of the TMV(s) 172, and conductors of the substrate 106.

The RDLs 210 are optional and are omitted in some embodiments. In such embodiments, if the die 202 is in a face-up orientation, the RDLs 104 can include conductors to route interconnections between the contacts 204 of the die 202 and other components of the device 100. Alternatively, if the die 202 is in a face-down orientation, the substrate 106 can include conductors to route interconnections between the contacts 204 of the die 202 and other components of the device 100.

Optionally, the die 202 can include one or more TSVs 214. In embodiments in which the die 202 includes TSV(s) 214, the TSV(s) 214 can form portions of conductive paths between the die 102 and the substrate 106.

Interconnecting the die 102, the die 202, and the dies of the die stack(s) 142 in the manner illustrated in FIG. 2 enables three-dimensional stacking of the dies of an integrated device (e.g., the device 100) in a low-cost manner. For example, in some embodiments, a multi-die die stack (e.g., die stack 142) can be interconnected with the die 102 without the use of TSVs, which increase semiconductor fabrication costs, decrease yield, and increase die size. Even in embodiments in which the die 202 includes the TSV(s) 214, use of RDLs of the die stack(s) 142 to route at least some of the electrical connections between the die 102 and the substrate 106 and/or between the die 202 and the substrate 106 can reduce the number of TSVs 214, which can reduce the size of the die 202 and may provide improvements in fabrication costs and yield as compared to routing the same connections using additional TSVs in the die 202.

### Exemplary Sequence for Fabricating an Integrated Device Having Multiple Die Orientations

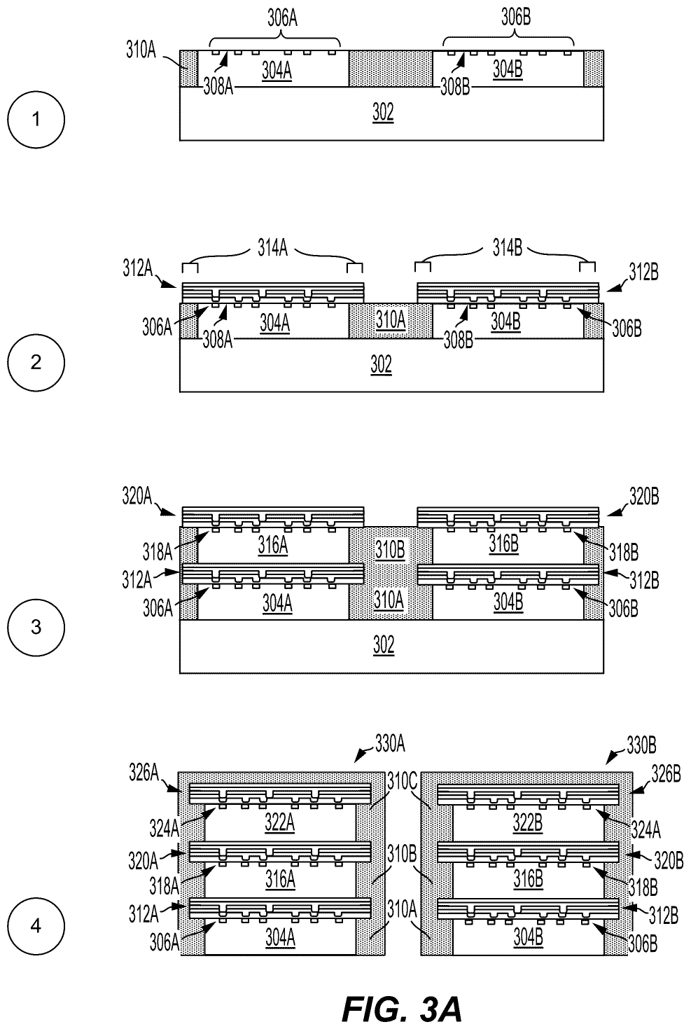

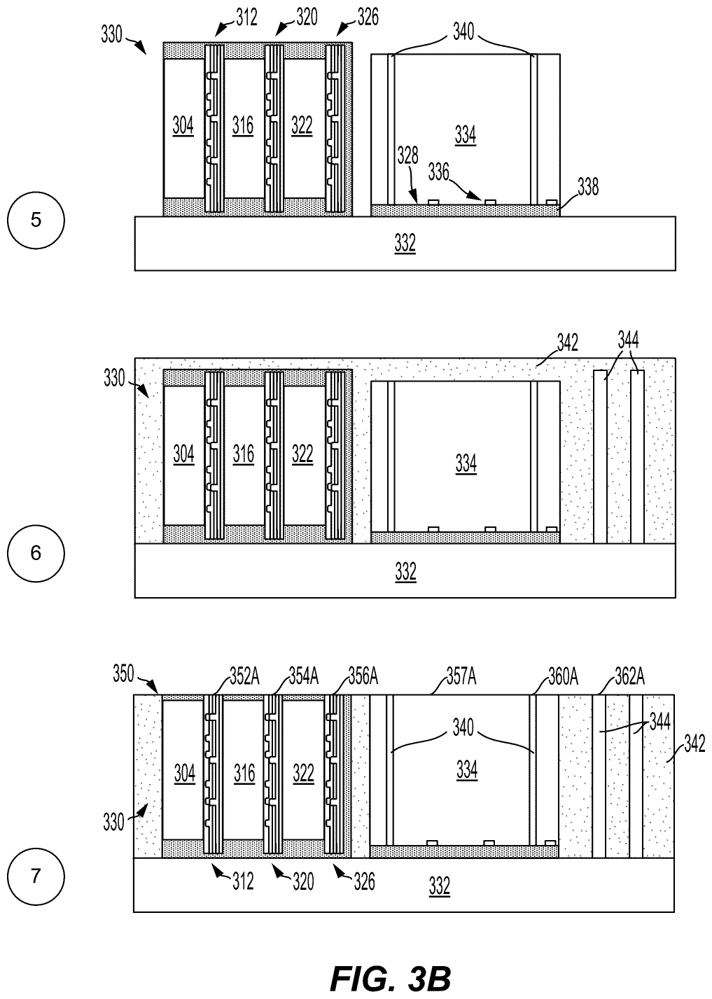

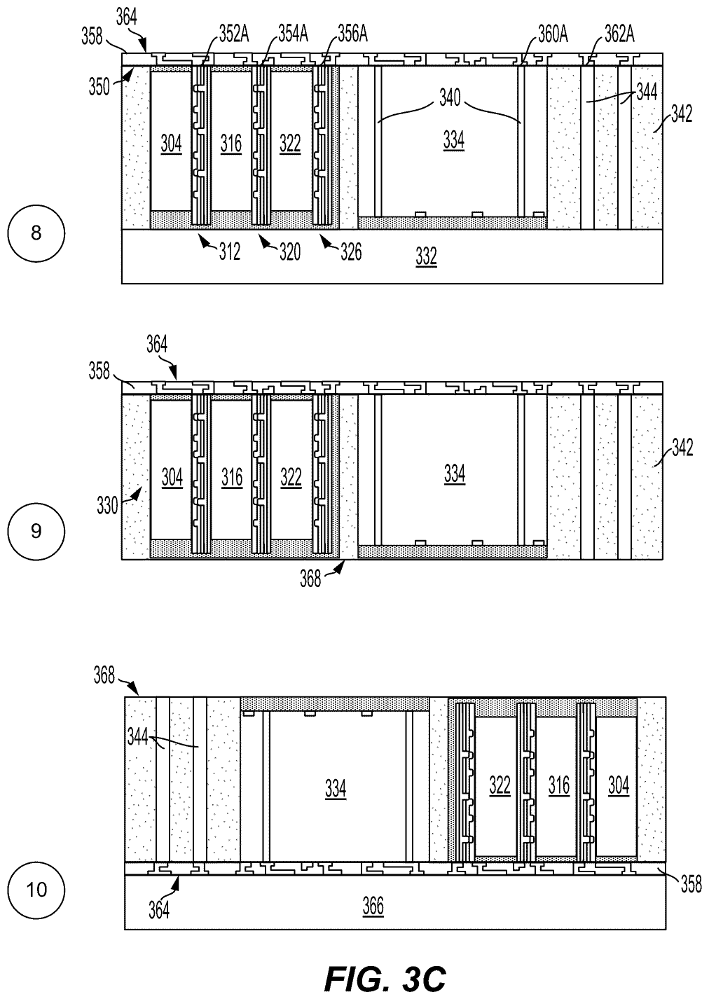

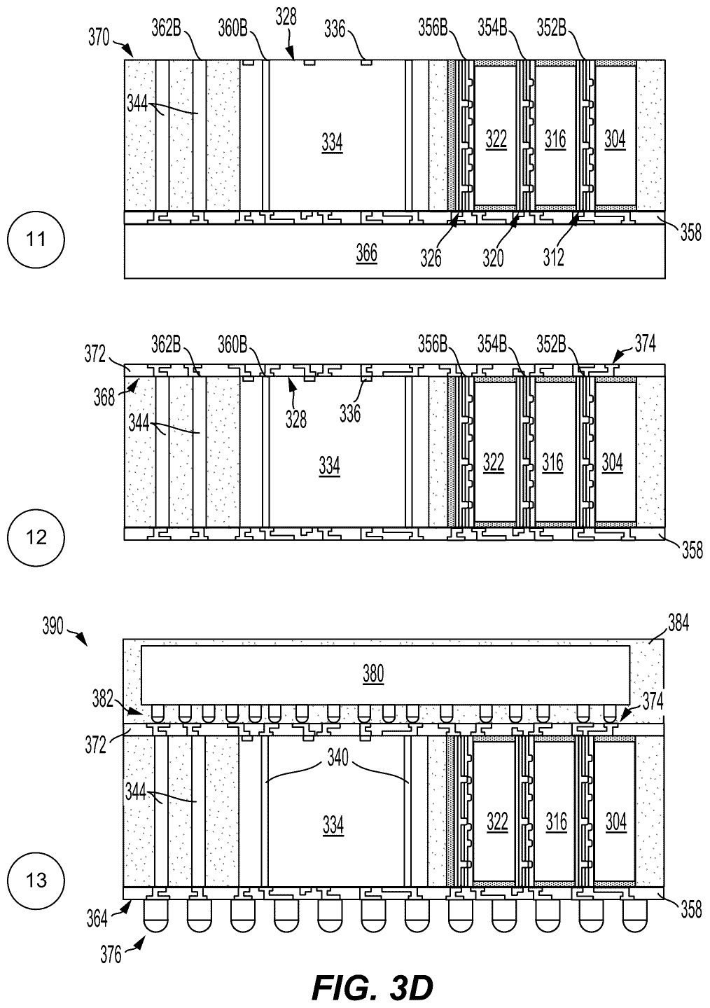

In some implementations, fabricating a device that includes dies with multiple die orientations (e.g., the device 100 of FIG. 1 or FIG. 2) includes several processes. FIGS. 3A-3D illustrate an exemplary sequence for providing or fabricating the device 100 that includes dies with multiple die orientations, as described with reference to FIG. 1 or FIG. 2. For example, the sequence of FIGS. 3A-3D can be used to provide (e.g., during fabrication of) a device that includes one or more first dies (e.g., the die 102 of FIGS. 1 and 2) connected to a first set of redistribution layers (e.g., the RDLs 104), the substrate 106, and one or more second dies (e.g., the die 110 and/or the dies 150) connected to a second set of redistribution layers (e.g., the RDLs 112 and/or the RDLs 152), where the first set of redistribution layers includes a first set of metal layers oriented along a first plane (e.g., the XY plane of FIG. 1), where the second set of redistribution layers includes a second set of metal layers oriented along a second plane (e.g., the ZY plane of FIG. 1), and where face(s) of the first die(s) (e.g., the face 160) are oriented non-parallel with respect to face(s) of the second die(s) (e.g., the face 164 of the die 110, and/or the face(s) of the dies 150).

It should be noted that the sequence of FIGS. 3A-3D may combine one or more stages in order to simplify and/or clarify the sequence for providing or fabricating a device with multiple die orientations. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-3D.

Stage 1 of FIG. 3A illustrates a state after one or more dies 304 (e.g., a die 304A and a die 304B) are coupled to a carrier 302 and partially encapsulated with a mold compound 310A. The carrier 302 can include a wafer, a panel, or a strip that supports concurrent formation of multiple dies stacks. In FIG. 3A, the dies 304 are attached to the carrier 302 in a face-up orientation. For example, contacts 306A on a face 308A of the die 304A and contacts 306B on a face 308B of the die 304B are oriented away from the carrier 302.

In a particular aspect, the die(s) 304 are coupled to the carrier 302 using one or more adhesive layers. The mold compound 310A can be applied using one or more deposition operations, such as spin-on operations, dispensing operations, etc. to apply the mold compound 310A to a surface of the carrier 302 and an area between the die(s) 304. If deposition of the mold compound 310A is performed in a manner that results in the mold compound 310A covering a portion of the face 308 of one of the die(s) 304, one or more additional operations may be performed to remove the mold compound 310A from the face(s) 308 of the die(s) 304. For example, operations to remove the mold compound 310A from the face(s) 308 of the die(s) 304 can include cleaning, etching, grinding or polishing, etc.

Stage 2 illustrates a state after formation of RDLs 312 on the die(s) 304. The RDLs 312 are electrically connected to the contacts 306 of the die(s) 304. The RDLs 312 include two or more metal layers separated from one another by dielectric layer(s). The metal layers are patterned to define traces and possibly other conductive features, and the metal layers are interconnected to one another by conductive vias. The RDLs 312 can be formed using one or more deposition operations, one or more lamination operations, or combinations thereof, to form metal layers and dielectric layer(s). In some embodiments, certain metal deposition operations may be guided by a patterned resist layer such that the metal layers are patterned to define traces as the metal layers are deposited, etc. Alternatively, metal layers can be deposited and patterned in subsequent operations, such as using one or more etch operations as guided by a patterned resist layer. In still other embodiments, metal layers can be patterned using ablative techniques (e.g., using laser ablation), or the metal layers can be applied in a patterned manner, such as using one or more printing operations.

In a particular aspect, the RDLs 312 at Stage 2 extend beyond edges of the die(s) 304. For example, RDLs 312A extend beyond edges of the die 304A in overhang regions 314A, and RDLs 312B extend beyond edges of the die 304B in overhang regions 314B. In some embodiments, the RDLs 312A are merged with the RDLs 312B. For example, although two separate stacks of layers corresponding to the RDLs 312A and 312B are illustrated in FIG. 3A, the RDLs 312A and 312B can include a single stack of layers that extends across the dies 304A, 304B and the overhang regions 314A, 314B, and areas therebetween. To illustrate, the mold compound 310A can be co-extensive with (e.g., extend to edges of) the carrier 302 such that an upper surface of the mold compound 310A together with upper surfaces (e.g., faces 308) of the dies 304 have an area equal to an area of a top side of the carrier 302. In this illustrative example, the RDLs 312 can also be co-extensive with the carrier 302 rather than separated as illustrated in FIG. 3A.

Stage 3 illustrates a state after additional die(s) 316 (including a die 316A and a die 316B) are stacked on the RDLs 312 and at least partially encapsulated in a mold compound 310B and after formation of additional RDLs 320 (including RDLs 320A and RDLs 320B). The RDLs 320 are electrically connected to the contacts 318 (including contacts 318A and contacts 318B) of the die(s) 316. The RDLs 320 include two or more metal layers separated from one another by dielectric layer(s). The metal layers are patterned to define traces and possibly other conductive features, and the metal layer are interconnected to one another by conductive vias. The RDLs 320 can be formed using one or more deposition and/or patterning operations as described above with reference to formation of the RDLs 312. The RDLs 320 extend beyond edges of the die(s) 316, and, in some embodiments, may be formed as a stack of layers that is co-extensive with (e.g., extends to edges of) the carrier 302 or one or more layers beneath the RDLs 320.

Stage 4 illustrates a state after removal of the carrier 302 and individuation of die stacks 330 (including a die stack 330A and a die stack 330B). The state illustrated at Stage 4 also follows optional steps to add one or more additional dies 322 (including a die 322A and a die 322B) and one or more additional RDLs 326 (including RDLs 326A and RDLs 326B) to the die stacks 330 prior to removal of the carrier 302 and individuation of the die stacks 330. The additional dies 322 and RDLs 326 are optional and are omitted in some embodiments. Further, while one additional die is added at Stage 4 to form die stack(s) 330 of three dies each in FIG. 3A, in other embodiments, the die stack(s) 330 include more than three dies, in which case some operations described with reference to Stages 3 and 4 can be repeated.

After a last die and associated RDLs are added to each die stack 330, the last dies and associated RDLs can be at least partially encapsulated in a mold compound 310C. For example, in FIG. 3A, the dies 322 and the RDLs 326 are fully encapsulated in the mold compound 310C. In other embodiments, a top layer of the RDLs 326 is not fully covered by the mold compound 310C. Further, as described with reference to Stage 2, in some embodiments, one or more of the sets of RDLs 312, 320, 326 can be co-extensive with the carrier 302, in which case individuation of the die stacks 330 includes cutting across one or more layers of the sets of RDLs 312, 320, 326. In such embodiments, the sets of RDLs 312, 320, 326 are not fully encapsulated in the mold compound 310.

Formation of the die stacks 330 is complete at Stage 4. In some embodiments, the die stacks 330A and 330B are duplicates. For example, in such embodiments, the die 304A and the die 304B are two instances of a single die design (e.g., each includes circuitry identical to the other), and the RDLs 312A and 312B are two instances of a single RDL design (e.g., each includes patterned layers identical to the other). In other embodiments, the die stacks 330A and 330B are different from one another. For example, in such embodiments, the die 304A includes circuitry distinct from circuitry of the die 304B and/or the RDLs 312A include patterned layers different from patterned layers of the RDLs 312B. When the die stacks 330A and 330B are different from one another, the dies at each layer of the die stacks 330 have substantially the same thickness to enable concurrent formation of RDLs on the dies.

Stage 5 of FIG. 3B illustrates a state after one or more die stacks 330 are coupled to a carrier 332 using an adhesive. For case of illustration, only one die stack 330 is illustrated in FIG. 3B (and in related FIGS. 3C and 3D); however, in some embodiments, more than one die stack 330 is coupled to the carrier 332. The die stack(s) 330 are rotated 90 degrees relative to the orientation illustrated at Stage 4 of FIG. 3A. In FIGS. 3B-3D, the die stack 330 include three dies (e.g., dies 304, 316, and 322) and three associated sets of RDLs (e.g., RDLs 312, 320, and 326); however, as described with reference to Stage 4 of FIG. 3A, the die stack 330 can include more than three or fewer than three dies and associated RDLs.

The state illustrated at Stage 5 also follows optional steps to couple one or more dies 334 to the carrier 332 using an adhesive. The die(s) 334 are optional and are omitted in some embodiments. For example, the die(s) 334 are attached to the carrier 332 at Stage 5 during fabrication of the device 100 of FIG. 2 and are omitted (e.g., are not attached to the carrier 332 at Stage 5) during fabrication of the device 100 of FIG. 1. For case of illustration, only one die 334 is illustrated in FIG. 3B (and in related FIGS. 3C and 3D); however, in some embodiments, more than one die 334 is coupled to the carrier 332.

The die(s) 334 are coupled to the carrier 332 in a face-down orientation such that contacts 336 of the die(s) 334 are toward the carrier 332. In the example illustrated in FIG. 3B, a spacer layer 338 is disposed between the die(s) 334 and the carrier 332. A thickness of the spacer layer 338 is selected to facilitate alignment of a face 328 of the die(s) 334 with ends of the RDLs 312, 320, 326 after processing described with reference to Stage 11 of FIG. 3D. In the example illustrated in FIGS. 3B-3D, the die(s) 334 include TSVs 340. The TSVs 340 are optional and are omitted in some embodiments.

Stage 6 illustrates a state after formation of a mold compound 342 over the die stack(s) 330 and the die(s) 334. In the example illustrated, Stage 6 also follows formation of one or more conductors 344, which are coupled to the carrier 332 and extend at least partially through the mold compound 342. The conductors 344 can be formed before or after formation of the mold compound 342. For example, the mold compound 342 can be applied to cover a surface of the carrier 332 to a depth that covers the die stack(s) 330 and the die 334 and cured. Subsequently, openings can be formed in the mold compound 342 (e.g., using one or more drilling or etching operations), and the conductors 344 can be formed within the openings using one or more deposition operations (e.g., plating). As another example, the one or more conductors 344 can be formed on the carrier 332 as guided by a patterned resist layer, which can subsequently be removed. In this example, the mold compound 342 can be formed after the patterned resist layer is removed.

Stage 7 illustrates a state after removal of at least a portion of the mold compound 342 to expose a surface 350. For example, the surface 350 can be formed using one or more grinding operations or other planarization operations. The surface 350 includes exposed ends of RDLs of the die stack(s) 330. For example, in FIG. 3B, the surface 350 includes exposed ends 352A of the RDLs 312, exposed ends 354A of the RDLs 320, and exposed ends 356A of the RDLs 326. The surface 350 also includes back(s) 357A of the die(s) 334, which may include end(s) 360A of the TSVs 340 if the die(s) 334 include the TSV(s) 340. Further, if the conductors 344 were formed at Stage 6, the surface 350 also includes exposed ends 362A of the conductors 344.

Stage 8 of FIG. 3C illustrates a state after formation of RDLs 358 on the surface 350. The RDLs 358 include two or more metal layers separated from one another by dielectric layer(s). The metal layers are patterned to define traces that define conductive paths between various conductive features of the surface 350 and contacts of a surface 364 of the RDLs 358. Dielectric layers of the RDLs 358 can be formed using one or more lamination operations (e.g., using dry film dielectric layers), one or more deposition operations (e.g., application of resin followed by curing), or combinations thereof. Metal layers of the RDLs 358 can be formed using one or more lamination operations (e.g., application of metal foil layers), one or more deposition operations (e.g., chemical vapor deposition, physical vapor deposition, electroplating, printing, etc.), or combinations thereof.

Stage 9 illustrates a state after removal of the carrier 332. Removing the carrier 332 exposes a surface 368 of the RDLs 358. Stage 10 illustrates a state after the structure illustrated at Stage 9 is flipped and the surface 364 of the RDLs 358 is attached to a carrier 366.

Stage 11 of FIG. 3D illustrates a state after removal of material to expose a surface 370. For example, removal of the material to expose the surface 370 can include performing one or more grinding operations (or other planarization operations), one or more etching operations, etc. Material removed to expose the surface 370 includes a portion of each of the RDLs 312, 320, 326, the spacer layer 338 (if used at Stage 5), a portion of the mold compound 342 formed at Stage 6, and a portion of each of the conductors 344 (if present).

The surface 370 includes exposed ends of RDLs of the die stack(s) 330. For example, in FIG. 3D, the surface 370 includes exposed ends 352B of the RDLs 312, exposed ends 354B of the RDLs 320, and exposed ends 356B of the RDLs 326. The surface 350 also includes the face(s) 328 of the die(s) 334, including contacts 336 of the die(s) 334. If the die(s) 334 include the TSV(s) 340, the face(s) 328 of the die(s) 334 also include ends 360B of the TSV(s) 340. The surface 370 also includes ends 362B of the conductors 344, if present.

Stage 12 illustrates a state after formation of RDLs 372 on the surface 370 and removal of the carrier 366. The RDLs 372 include two or more metal layers separated from one another by dielectric layer(s). The metal layers of the RDLs 372 are patterned to define traces that form conductive paths between various conductive features of the surface 370 and contacts of a surface 374 of the RDLs 372. The RDLs 372 can be formed using operations described with reference to formation of the RDLs 358 of Stage 8.

Stage 13 illustrates a state after attachment of one or more dies 380 to the RDLs 372 via interconnects 382 that are electrically connected to corresponding contacts on the surface 374 of the RDLs 372. In the example illustrated in FIG. 3D, Stage 13 also follows formation of off-package interconnects 376, which are electrically connected to contacts on the surface 364 of the RDLs 358 and at least partial encapsulation of the die 380 in a mold compound 384.

Fabrication of a device 390 is complete at Stage 13. In the example illustrated in FIG. 3D, the device 390 is an example of the device 100 of FIG. 2. However, the operations described above with reference to Stages 5-13 can be performed without the die(s) 334 to form the device 100 of FIG. 1. The device 390 also illustrates other optional components, such as the conductors 344, the TSVs 340, and the mold compound 384, any or all of which can be omitted in some embodiments.

Stages 1-4 of FIG. 3A are optional and are omitted in some embodiments of a sequence to fabricate the device 390 of FIG. 3D. For example, the die stack(s) 330 can be fabricated by another entity and can be obtained (e.g., purchased) for use in fabricating the device 390, in which case the sequence to fabricate the device 390 can start at Stage 5. The order of some operations of the sequence to fabricate the device 390 described with reference to FIGS. 3A-3D can be changed without changing the resulting device 390. For example, the carrier 366 can be removed after the die 380 is attached (at Stage 13) rather than after the RDLs 372 are formed (at Stage 12). As another example, the conductors 344 can be formed through the mold compound 342 after formation of the RDLs 358, such as at Stage 10, rather than at Stage 6.

### Exemplary Flow Diagram of a Method for Fabricating Integrated Device Having Multiple Die Orientations

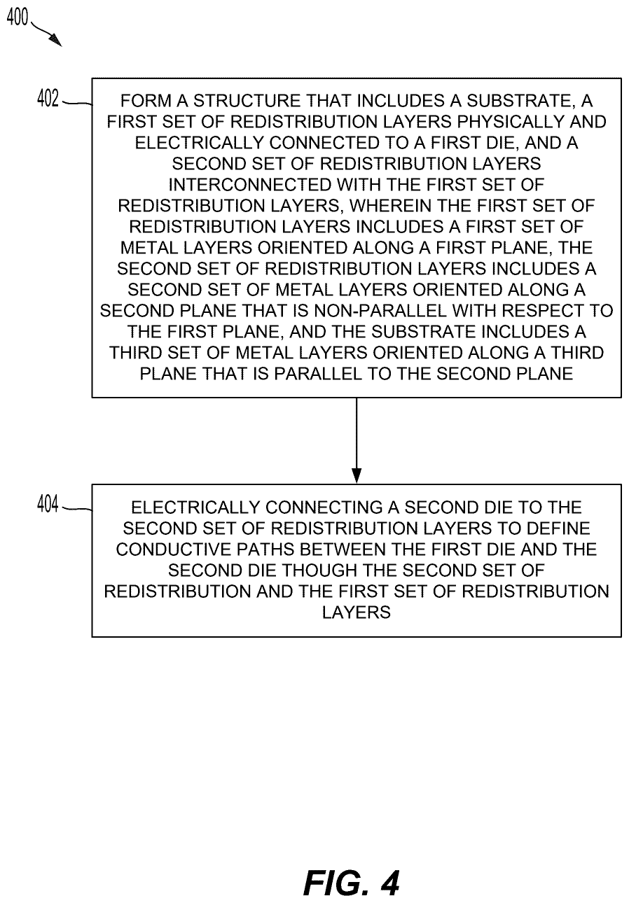

In some implementations, fabricating an integrated device having multiple die orientations includes several processes. FIG. 4 illustrates an exemplary flow diagram of a method 400 for providing or fabricating an integrated device having multiple die orientations. In some implementations, the method 400 of FIG. 4 may be used to provide or fabricate the device 100 of FIG. 1 or FIG. 2 or the device 390 of FIG. 3D.

It should be noted that the flow diagram of the method 400 illustrated in FIG. 4 may combine one or more processes in order to simplify and/or clarify the method 400 for providing or fabricating an integrated device having multiple die orientations.

The method 400 includes, at block 402, forming a structure that includes a substrate, a first set of redistribution layers physically and electrically connected to a first die, and a second set of redistribution layers interconnected with the first set of redistribution layers, wherein the first set of redistribution layers includes a first set of metal layers oriented along a first plane, the second set of redistribution layers includes a second set of metal layers oriented along a second plane that is non-parallel with respect to (e.g., is orthogonal to or angularly offset from) the first plane, and the substrate includes a third set of metal layers oriented along a third plane that is parallel to the second plane. For example, the structure can include the structure illustrated at Stage 12 of FIG. 3D. In this example, the first die corresponds to any of the dies 304, 316, or 322, and the first set of redistribution layers corresponds to the RDLs 312, 320, 326 associated with the first die. Further, in this example, the substrate corresponds to the RDLs 358, and the second set of RDLs corresponds to the RDLs 372. Thus, the substrate, the first set of redistribution layers, and the second set of redistribution layers can be formed using various operations described with reference to Stages 1-12 of FIGS. 3A-3D.

The structure may also include a mold compound disposed between the second set of redistribution layers and the substrate to at least partially encapsulate the first die and the first set of redistribution layers. For example, the mold compound can correspond to the mold compound 342 of FIGS. 3B-3D. In embodiments in which the structure includes the mold compound, the structure can also include one or more TMVs extending through the mold compound and electrically connecting one or more contacts of the substrate to one or more contacts of the second set of redistribution layers. For example, the TMVs can correspond to the conductors 344 of FIGS. 3B-3D.

The method 400 also includes, at block 404, electrically connecting a second die to the second set of redistribution layers to define conductive paths between the first die and the second die through the second set of redistribution layers and the first set of redistribution layers. For example, the second die can correspond to the die 380 of Stage 13 of FIG. 3D, which is electrically connected to the die 304 through the RDLs 372 and the RDLs 312 (and in Stage 13 of FIG. 3D is also electrically connected to the die 316 through the RDLs 372 and the RDLs 320 and to the die 322 through the RDLs 372 and the RDLs 326).

In some embodiments of the method 400, forming the structure includes exposing ends of conductors of the first set of redistribution layers and forming conductors of the second set of redistribution layers on the ends of the conductors of the first set of redistribution layers. For example, exposing ends of conductors of the first set of redistribution layers can include performing material removal operations, such as grinding and/or etching, as described with reference to Stage 11 of FIG. 3D, to expose ends 352B, 354B, and/or 356B of the RDLs 312, 320, 326. In this example, forming conductors of the second set of redistribution layers on the ends of the conductors of the first set of redistribution layers includes performing various deposition and patterning operations as described with reference to formation of the RDLs 372 at Stage 12 of FIG. 3D.

In some embodiments of the method 400, the structure also includes a third die disposed between the substrate and the second set of redistribution layers such that a face of the third die is oriented along a plane parallel to the second plane. For example, the third die can correspond to one of the die(s) 334 of FIGS. 3B-3D, which are oriented such that the face(s) 328 of the die(s) 334 are parallel to the metal layer(s) of the RDLs 372 of FIG. 3D.

In some embodiments, the method 400 also includes forming a die stack that includes the first die, the first set of redistribution layers, one or more additional dies, and one or more additional sets of redistribution layers. For example, the die stack can correspond to the die stack 330 of FIG. 3B, which can be formed as described with reference to Stages 1-4 of FIG. 3A.

In some embodiments, the method 400 also includes forming the substrate as a third set of redistribution layers. In such embodiments, the second set of redistribution layers are physically and electrically connected to first ends of the first set of redistribution layers and the third set of redistribution layers are physically and electrically connected to second ends of the first set of redistribution layers. For example, the substrate can include the RDLs 358 of FIG. 3D, which are formed on ends of the RDLs 312, 320, 326, using operations described with reference to Stage 8 of FIG. 3C, opposite the RDLs 372 which are formed using operations described with reference to Stage 12 of FIG. 3D.

### Exemplary Electronic Devices

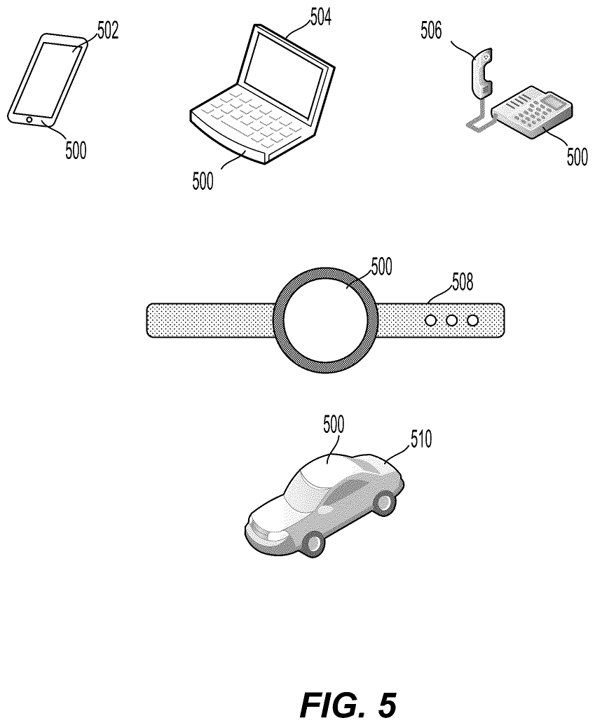

FIG. 5 illustrates various electronic devices that may include or be integrated with a device that includes dies with multiple die orientations, such as any of the devices 100 or 390. For example, a mobile phone device 502, a laptop computer device 504, a fixed location terminal device 506, a wearable device 508, or a vehicle 510 (e.g., an automobile or an aerial device) may include a device 500. The device 500 can include, be included with, or correspond to any of the devices 100 of FIG. 1 or FIG. 2, or the device 390 of FIG. 3D, as described herein. The devices 502, 504, 506 and 508 and the vehicle 510 illustrated in FIG. 5 are merely exemplary. Other electronic devices may also feature the device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-5 may be rearranged and/or combined into a single component, process, feature or function or embodied in several components, processes, or functions. Additional elements, components, processes, and/or functions may also be added without departing from the disclosure. It should also be noted FIGS. 1-5 and its corresponding description in the present disclosure is not limited to dies and/or ICs. In some implementations, FIGS. 1-5 and its corresponding description may be used to manufacture, create, provide, and/or produce devices and/or integrated devices.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a first die physically and electrically connected to a first set of redistribution layers, the first set of redistribution layers including a first set of metal layers oriented along a first plane; a substrate; and a second die disposed between the first set of redistribution layers and the substrate and physically and electrically connected to a second set of redistribution layers, the second set of redistribution layers including a second set of metal layers oriented along a second plane, wherein the second plane is non-parallel with respect to the first plane, and wherein the second set of metal layers define conductive paths between various combinations of the substrate, the first die, and the second die.

Example 2 includes the device of Example 1, wherein the second plane is orthogonal to the first plane.

Example 3 includes the device of Example 1 or Example 2, wherein at least one metal trace of the second set of metal layers is electrically connected at a first end to a contact of the first set of redistribution layers and is electrically connected at a second end to a contact of the substrate.

Example 4 includes the device of any of Examples 1 to 3, wherein the first set of redistribution layers includes a first set of conductive vias interconnecting various first traces of the first set of metal layers, the first set of conductive vias oriented along a first direction; and wherein the second set of redistribution layers includes a second set of conductive vias interconnecting various second traces of the second set of metal layers, the second set of conductive vias oriented along a second direction that is perpendicular to the first direction.

Example 5 includes the device of any of Examples 1 to 4, wherein the first die includes first active circuitry, and the second die includes second active circuitry.

Example 6 includes the device of any of Examples 1 to 5, wherein the first die includes circuitry defining one or more processor cores and the second die includes circuitry defining a plurality of memory elements.

Example 7 includes the device of any of Examples 1 to 6, wherein the first die includes first active circuitry, and the second die includes one or more inductors, one or more capacitors, or both.

Example 8 includes the device of any of Examples 1 to 7 and further includes a die stack that includes the second die and the second set of redistribution layers and further includes one or more additional dies and one or more additional sets of redistribution layers, wherein each of the one or more additional sets of redistribution layers includes metal layers oriented along the second plane.

Example 9 includes the device of any of Examples 1 to 8, wherein the first die includes a first set of contacts on a first surface that is parallel to the first plane and the second die includes a second set of contacts on a second surface that is parallel to the second plane.

Example 10 includes the device of any of Examples 1 to 9 and further includes a third die disposed between the first set of redistribution layers and the substrate, the third die including a third set of contacts on a third surface that is parallel to the first plane.

Example 11 includes the device of any of Examples 1 to 10 and further includes a mold compound disposed between the first set of redistribution layers and the substrate and at least partially encapsulating the second die and the second set of redistribution layers.

Example 12 includes the device of Example 11 and further includes one or more TMVs extending through the mold compound, wherein each TMV electrically connects a contact of the substrate to a contact of the first set of redistribution layers.

According to Example 13, a method of fabrication includes forming a structure that includes a substrate, a first set of redistribution layers physically and electrically connected to a first die, and a second set of redistribution layers interconnected with the first set of redistribution layers, wherein the first set of redistribution layers includes a first set of metal layers oriented along a first plane, the second set of redistribution layers includes a second set of metal layers oriented along a second plane that is non-parallel with respect to the first plane, and the substrate includes a third set of metal layers oriented along a third plane that is parallel to the second plane; and electrically connecting a second die to the second set of redistribution layers to define conductive paths between the first die and the second die through the second set of redistribution layers and the first set of redistribution layers.

Example 14 includes the method of Example 13, wherein the second plane is orthogonal to the first plane.

Example 15 includes the method of Example 13 or Example 14, wherein forming the structure includes exposing ends of conductors of the first set of redistribution layers, and forming conductors of the second set of redistribution layers on the ends of the conductors of the first set of redistribution layers.

Example 16 includes the method of any of Examples 13 to 15 and further includes forming a die stack that includes the first die, the first set of redistribution layers, one or more additional dies, and one or more additional sets of redistribution layers.

Example 17 includes the method of any of Examples 13 to 16 and further includes forming the substrate as a third set of redistribution layers, wherein the second set of redistribution layers are physically and electrically connected to first ends of the first set of redistribution layers and the third set of redistribution layers are physically and electrically connected to second ends of the first set of redistribution layers.

Example 18 includes the method of any of Examples 13 to 17, wherein the structure further includes a third die disposed between the substrate and the second set of redistribution layers and having a face oriented along a plane parallel to the second plane.

Example 19 includes the method of any of Examples 13 to 18, wherein the structure further includes a mold compound disposed between the second set of redistribution layers and the substrate to at least partially encapsulate the first die and the first set of redistribution layers.

Example 20 includes the method of Example 19, wherein the structure further comprises one or more TMVs extending through the mold compound and electrically connecting one or more contacts of the substrate to one or more contacts of the second set of redistribution layers.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a first die physically and electrically connected to a first set of redistribution layers, the first set of redistribution layers including a first set of metal layers oriented along a first plane;
a substrate; and
a second die disposed between the first set of redistribution layers and the substrate and physically and electrically connected to a second set of redistribution layers, the second set of redistribution layers including a second set of metal layers oriented along a second plane,
wherein the second plane is non-parallel with respect to the first plane, and wherein the second set of metal layers define conductive paths between various combinations of the substrate, the first die, and the second die.

2. The device of claim 1, wherein the second plane is orthogonal to the first plane.

3. The device of claim 1, wherein at least one metal trace of the second set of metal layers is electrically connected at a first end to a contact of the first set of redistribution layers and is electrically connected at a second end to a contact of the substrate.

4. The device of claim 1, wherein:
the first set of redistribution layers includes a first set of conductive vias interconnecting various first traces of the first set of metal layers, wherein the first set of conductive vias are oriented along a first direction; and
the second set of redistribution layers includes a second set of conductive vias interconnecting various second traces of the second set of metal layers, wherein the second set of conductive vias are oriented along a second direction that is perpendicular to the first direction.

5. The device of claim 1, wherein the first die includes first active circuitry, and the second die includes one or more inductors, one or more capacitors, or both.

6. The device of claim 1, wherein the first die includes first active circuitry, and the second die includes second active circuitry.

7. The device of claim 1, wherein the first die includes circuitry defining one or more processor cores and the second die includes circuitry defining a plurality of memory elements.

8. The device of claim 1, further comprising a die stack that includes the second die and the second set of redistribution layers and further includes one or more additional dies and one or more additional sets of redistribution layers, wherein each of the one or more additional sets of redistribution layers includes metal layers oriented along the second plane.

9. The device of claim 1, wherein the first die includes a first set of contacts on a first surface that is parallel to the first plane and the second die includes a second set of contacts on a second surface that is parallel to the second plane.

10. The device of claim 9, further comprising a third die disposed between the first set of redistribution layers and the substrate, the third die including a third set of contacts on a third surface that is parallel to the first plane.

11. The device of claim 1, further comprising a mold compound disposed between the first set of redistribution layers and the substrate and at least partially encapsulating the second die and the second set of redistribution layers.

12. The device of claim 11, further comprising one or more through mold vias extending through the mold compound, wherein each through mold via electrically connects a contact of the substrate to a contact of the first set of redistribution layers.

13. A method of fabrication comprising:
forming a structure that includes a substrate, a first set of redistribution layers physically and electrically connected to a first die, and a second set of redistribution layers interconnected with the first set of redistribution layers, wherein the first set of redistribution layers includes a first set of metal layers oriented along a first plane, the second set of redistribution layers includes a second set of metal layers oriented along a second plane that is non-parallel with respect to the first plane, and the substrate includes a third set of metal layers oriented along a third plane that is parallel to the second plane; and
electrically connecting a second die to the second set of redistribution layers to define conductive paths between the first die and the second die through the second set of redistribution layers and the first set of redistribution layers.

14. The method of claim 13, wherein the second plane is orthogonal to the first plane.

15. The method of claim 13, wherein forming the structure includes:
exposing ends of conductors of the first set of redistribution layers; and
forming conductors of the second set of redistribution layers on the ends of the conductors of the first set of redistribution layers.

16. The method of claim 13, further comprising forming a die stack that includes the first die, the first set of redistribution layers, one or more additional dies, and one or more additional sets of redistribution layers.

17. The method of claim 13, further comprising forming the substrate as a third set of redistribution layers, wherein the second set of redistribution layers are physically and electrically connected to first ends of the first set of redistribution layers and the third set of redistribution layers are physically and electrically connected to second ends of the first set of redistribution layers.

18. The method of claim 13, wherein the structure further comprises a third die disposed between the substrate and the second set of redistribution layers and having a face oriented along a plane parallel to the second plane.

19. The method of claim 13, wherein the structure further comprises a mold compound disposed between the second set of redistribution layers and the substrate to at least partially encapsulate the first die and the first set of redistribution layers.

20. The method of claim 19, wherein the structure further comprises one or more through mold vias extending through the mold compound and electrically connecting one or more contacts of the substrate to one or more contacts of the second set of redistribution layers.
